(19) United States
(12) Patent Application Publication
(10) Pub. No.: US 2017/0262179 A1
(43) Pub. Date: Sep. 14, 2017

(54) MEMORY SYSTEM AND MEMORY SYSTEM CONTROLLING METHOD

(71) Applicant: KABUSHIKI KAISHA TOSHIBA, Tokyo (JP)

(72) Inventor: Taichi SUIZU, Yamato Kanagawa (JP)

(21) Appl. No.: 15/445,759

(22) Filed: Feb. 28, 2017

Related U.S. Application Data
(60) Provisional application No. 62/305,923, filed on Mar. 9, 2016.

(51) Int. Cl. G06F 3/06; G11C 11/419

(52) U.S. Cl. CPC G06F 3/0604; G11C 11/419; G06F 3/0688; G06F 3/061; G06F 3/0659

(57) ABSTRACT

A memory system comprises a communication interface for transmitting commands and data to a host and receiving commands and data from the host. A storage medium has a first region for storing user data and a second region storing a plurality of first programs. Each first program sets parameters of a signal transmission process to be performed using the communication interface. Each first program has at least one different parameter from the other first programs in the plurality. A controller selects and executes a first program from the plurality of first programs according to a result of a first communication attempt between the communication interface and the host.

### CROSS-REFERENCE TO RELATED APPLICATIONS

This application is based upon and claims the benefit of priority from U.S. Provisional Patent Application No. 62/305,923, filed on Mar. 9, 2016, the entire contents of which are incorporated herein by reference.

### FIELD

Embodiments described herein relate generally to a memory system and a memory system controlling method.

### BACKGROUND

A memory system is equipped with firmware for writing and reading data to and from a storage medium.

### BRIEF DESCRIPTION OF THE DRAWINGS

FIG. 1 is a diagram illustrating an example of a memory system of a first embodiment.

FIG. 2 is a diagram illustrating an example of a serial interface of the first embodiment.

FIG. 3 is a diagram illustrating an example of a relationship between a PIN identifier (PINID) and a function of a signal terminal in the serial interface of the first embodiment.

FIG. 4 is a block diagram illustrating an example of a main controller of the first embodiment.

FIG. 5 is a diagram illustrating an example of an address conversion table of the first embodiment.

FIG. 6 is a diagram illustrating an example of a region of a NAND memory of the first embodiment.

FIG. 7 is a diagram illustrating an example of program information stored in the memory system of the first embodiment.

FIG. 8A is a diagram illustrating an example of programs stored in the NAND memory and a static random-access memory (SRAM) in the memory system of the first embodiment.

FIG. 8B is a diagram illustrating an example of programs stored in the NAND memory and the SRAM in the memory system of the first embodiment.

FIG. 8C is a diagram illustrating an example of programs stored in the NAND memory and the SRAM in the memory system of the first embodiment.

FIG. 9 is a flowchart illustrating an example of a flow of a process of activating the first program in the memory system of the first embodiment.

FIG. 10 is a block diagram illustrating an example of a main controller when a second program is activated in the first embodiment.

FIG. 11 is a diagram illustrating another example of a storage region of the NAND memory of a second embodiment.

FIG. 12 is a flowchart illustrating an example of a flow of another process of activating the first program in the memory system of the second embodiment.

FIG. 13 is a diagram illustrating an example of a storage region of a NAND memory in a third embodiment.

FIG. 14 is a flowchart illustrating an example of a flow of a process in the third embodiment.

FIG. 15 is a block diagram illustrating an example of a main controller when a third program is activated in the third embodiment.

FIG. 16 is a diagram illustrating an example of a storage region of a NAND memory in a fourth embodiment.

FIG. 17 is a flowchart illustrating an example of a flow of a process in the fourth embodiment.

FIG. 18 is a block diagram illustrating an example of a main controller when a fourth program is activated in the fourth embodiment.

FIG. 19 is a diagram illustrating an example of a storage region of a NAND memory in a fifth embodiment.

FIG. 20 is a flowchart illustrating an example of a flow of a process in the fifth embodiment.

FIG. 21 is a diagram illustrating an example of programs stored in the NAND memory and an SRAM in the memory system of the fifth embodiment.

FIG. 22 is a block diagram illustrating an example of a main controller when a fifth program is activated in the fifth embodiment.

FIG. 23 is a flowchart illustrating a modified example.

FIG. 24 is a diagram illustrating an example of a memory system of a sixth embodiment.

### DETAILED DESCRIPTION

In one embodiment, a memory system includes a communication interface for transmitting commands and data to a host and receiving commands and data from the host. A storage medium has a first region for storing user data and a second region storing a plurality of first programs. Each first program is for setting parameters of a signal transmission process to be performed using the communication interface. Each first program has at least one different parameter from the other first programs in the plurality. A controller is configured to select and execute a first program from the plurality of first programs according to a result of a first communication attempt between the communication interface and the host.

Hereinafter, memory systems and methods of example embodiments will be described with reference to the drawings.

### First Embodiment

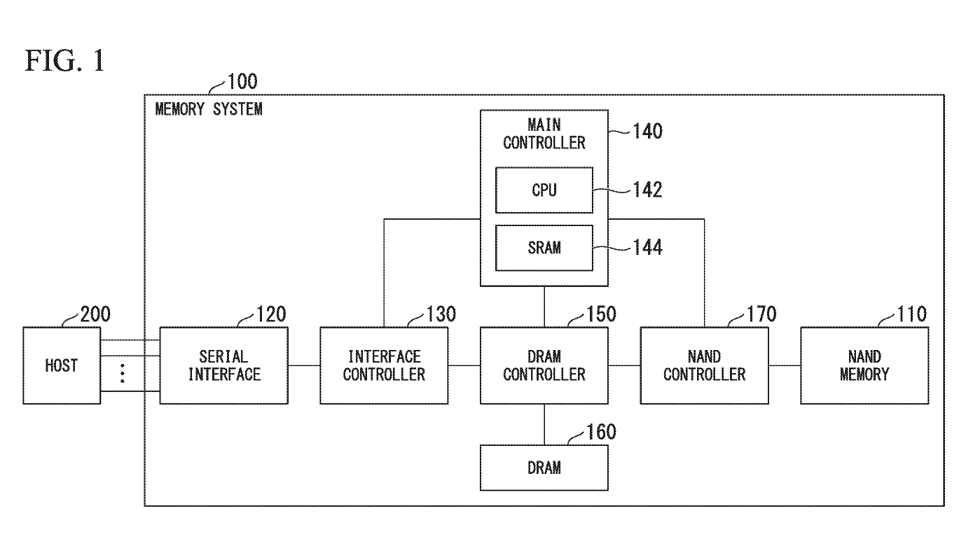

FIG. 1 is a diagram illustrating an example of the memory system of the first embodiment. The memory system 100 transmits/receives commands and data to/from a host device 200. The memory system 100 functions as an external storage device of the host device 200.

The host device 200 may be, for example, an information processing device, such as a personal computer or a server device, a portable phone, an imaging device, a portable terminal, such as a tablet computer or a smartphone, a game machine, or an in-vehicle terminal, such as a car navigation system. When user data written to the memory system 100 is to be read, the host device 200 transmits a read command to the memory system 100. When user data associated with the read command is transmitted by the memory system 100, the host device 200 receives user data. When user data is written to the memory system 100, the host device 200 transmits a write command and the user data to the memory system 100. When the user data of the memory system 100 is to be erased, the host device 200 transmits an erase command to the memory system 100. The user data includes data to be written to NAND memory based on the write command received from the host device 200 and data previously written to the NAND memory according to a write command.

The memory system 100 is a solid state drive (SSD), but is not limited thereto. The memory system 100 includes a NAND memory 110, a serial interface 120, an interface controller 130, a main controller 140, a dynamic random access memory (DRAM) controller 150, a DRAM 160, and a NAND controller 170, but is not limited thereto.

The NAND memory 110 is an example of a storage medium. The NAND memory 110 includes a non-volatile semiconductor memory. User data and program data can be stored in the NAND memory 110. Also, in the first embodiment, the “data” includes the “user data” and the “program data.” The “user data” includes data still to be written to the NAND memory 110 based on the write command already transmitted by the host device 200 and data that has already been written to the NAND memory 110. Further, the “user data” includes data read from the NAND memory 110 based on a read command transmitted by the host device 200. The “program data” is data of a program to be executed in the memory system 100. The “program data” includes data written to the NAND memory 110, data read from the NAND memory 110, and data stored in a storage region other than the NAND memory 110.

Also, the program in the first embodiment is firmware that is pre-stored in the NAND memory 110 and executed within the memory system 100, but is not limited thereto. The program in the first embodiment is not limited to that pre-stored in the NAND memory 110 and may be a program which was transmitted from an external device to the memory system 100 and then added to the NAND memory 110.

The serial interface 120 transmits and receives commands and data to and from the memory system 100 according to a predetermined interface standard. The interface standard is non-volatile memory express (NVMe), serial advanced technology attachment (SATA), or the like. Also, the interface standard is not limited to NVMe or SATA, and the communication interface standard may be serial attached SCSI (SAS) or peripheral components interconnect express (PCIe).

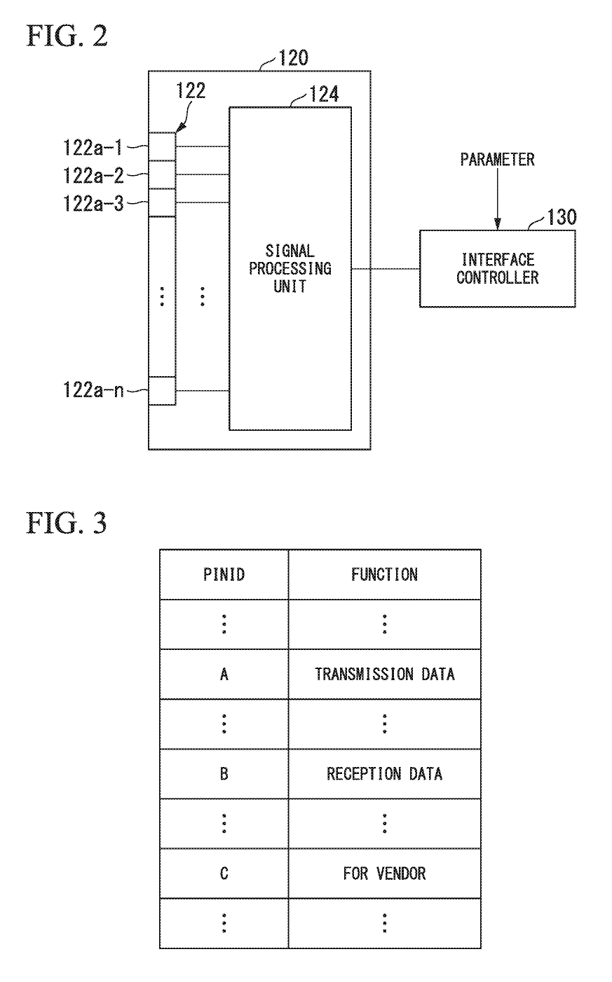

FIG. 2 is a diagram illustrating an example of a serial interface of the first embodiment. The serial interface 120 is an example of a communication interface. The serial interface 120 includes a connector 122 and a signal processing unit 124, but is not limited thereto. The connector 122 includes a plurality of signal terminals 122a-1, 122a-2, 122a-3, . . . and 122a-n (n is a natural number greater than 3). The connector 122 can be physically connected to a communication cable (not illustrated) which connects the memory system 100 and the host device 200. The signal terminals 122a-1, 122a-2, 122a-3, . . . and 122a-n are electrically connected to a signal line in the communication cable when the communication cable is connected to the memory system 100. In the following description, any of the signal terminals (122a-1, 122a-2, 122a-3, . . . and 122a-n) may be called a signal terminal 122a if the signal terminal need not be specifically distinguished from other signal terminals.

The signal processing unit 124 includes an analog-to-digital (A/D) conversion circuit and a signal modulation/demodulation circuit, but is not limited thereto. The signal processing unit 124 is connected to each of the plurality of signal terminals 122a in the connector 122. If a signal is supplied via the signal terminal 122a, the signal processing unit 124 executes a predetermined demodulation process to generate user data or a command. The signal processing unit 124 then outputs the generated user data or command to the interface controller 130. The signal processing unit 124 generates a transmission signal by executing a predetermined modulation process when data or a command is supplied via the interface controller 130. The signal processing unit 124 then outputs the generated transmission signal to any one signal terminal 122a of the plurality of signal terminals 122a.

FIG. 3 is a diagram illustrating an example of a relationship between a PINID and a function of the signal terminal in the serial interface of the first embodiment. The PINID is information such as a number for identifying the signal terminal 122a or the like. The function designates a type or a field of application of data allocated to the signal terminal 122a, but is not limited thereto. In the example shown in FIG. 3, transmission data is allocated to the signal terminal 122a having a PINID of “A,” reception data is allocated to the signal terminal 122a having a PINID of “B,” and a vendor-specific signal is allocated to the signal terminal 122a having a PINID of “C.”

The interface controller 130 can be a control integrated circuit (IC) which controls the serial interface 120, but is not limited thereto. The interface controller 130 outputs a command and user data output by the signal processing unit 124 to the main controller 140 and the DRAM controller 150. Also, the interface controller 130 outputs a command and data output by the main controller 140 to the signal processing unit 124. The interface controller 130 sets a signal transmission process of the signal processing unit 124 based on a parameter supplied from the main controller 140. The parameter may include information indicating amplitude and a signal processing format of a signal to be transmitted from the serial interface 120 to the host device 200, but is not limited thereto. The signal processing unit 124 outputs a signal at the amplitude set by the parameter to the signal terminal 122a.

A signal processing scheme is a scheme of adjusting a signal to be output from the signal processing unit 124 to the signal terminal 122a, but is not limited thereto. As a scheme of adjusting a signal, either of pre-emphasis and de-emphasis is selected. If the pre-emphasis is set, the signal processing unit 124 outputs a signal obtained by amplifying a high-frequency component which might be attenuated within the communication cable to the signal terminal 122a. If the de-emphasis is set, the signal processing unit 124 outputs a signal obtained by attenuating a low-frequency component according to the high-frequency component which might be attenuated within the communication cable to the signal terminal 122a.

The main controller 140 includes a central processing unit (CPU) 142 and an SRAM 144, but is not limited thereto. The main controller 140 may be implemented by hardware such as large scale integration (LSI), application specific integrated circuit (ASIC), or field-programmable gate array (FPGA) in addition to (or in place of) the CPU or implemented by a combination of hardware and a program. The CPU 142 executes a program written to the SRAM 144. The SRAM 144 is a volatile semiconductor memory. The SRAM 144 functions as a cache memory of the CPU 142. A program to be executed by the CPU 142 is written to the SRAM 144.

The DRAM controller 150 is a control IC which controls writing and reading of data and a command for the DRAM 160, but is not limited thereto. The DRAM 160 is a volatile semiconductor memory. The DRAM 160 functions as a main memory of the CPU 142. User data designated by a write command (hereinafter also referred to as write data) can be written to the DRAM 160. Thereby, the DRAM 160 functions as a write buffer. User data that is read based on a read command (hereinafter also referred to as read data) can be written to the DRAM 160. Thereby, the DRAM 160 functions as a read buffer. A command transmitted by the host device 200 can be written to the DRAM 160. Thereby, the DRAM 160 functions as a command buffer.

A program to be executed by the CPU 142 may be written to the DRAM 160. If the program to be executed by the CPU 142 cannot be written to the SRAM 144, the program may be written by the DRAM controller 150.

The NAND controller 170 may include a NAND interface circuit which performs an interface process for the NAND memory 110, an error correction circuit, a DMA controller, etc., but is not limited thereto. The NAND controller 170 receives a write request based on a write command from the main controller 140. The NAND controller 170 can write user data that was temporarily stored in the DRAM 160 to the NAND memory 110 based on the write request. The NAND controller 170 receives a read request based on the read command from the main controller 140. Based on the read request, the NAND controller 170 reads user data stored in the NAND memory 110 and then outputs the read user data to the DRAM controller 150. The NAND controller 170 can receive an erase request based on an erase command from the main controller 140. Based on the erase request, the NAND controller 170 erases user data stored in the NAND memory 110.

Further, read requests and write requests for the memory system 100 to manage the NAND memory 110 are output to the NAND controller 170. The NAND controller 170 reads data from the NAND memory 110 for output of the read data to the DRAM controller 150 based on the read request. The NAND controller 170 reads data from the DRAM 160 for write of data to the NAND memory 110 based on the write request.

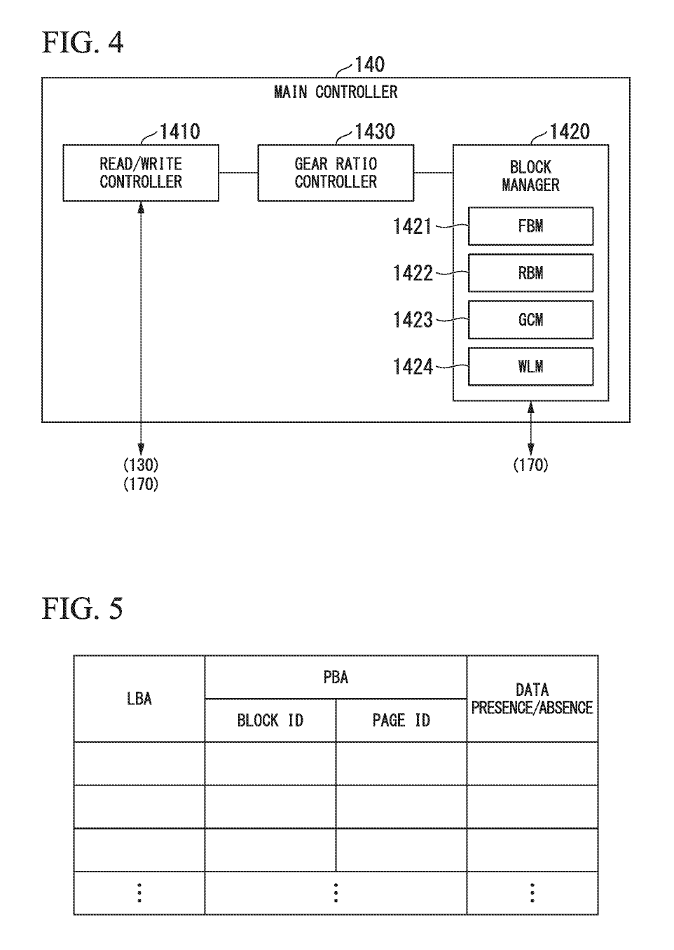

FIG. 4 is a block diagram illustrating an example of a main controller of the first embodiment. The main controller 140 includes a read/write controller 1410, a block manager 1420, and a gear ratio controller 1430, but is not limited thereto. The read/write controller 1410, the block manager 1420, and the gear ratio controller 1430 are implemented by the CPU 142 executing a first program stored in the SRAM 144, the DRAM 160, or the NAND memory 110.

The read/write controller 1410 receives a write command transmitted by the interface controller 130. When a write command and write data associated with the write command are received, the read/write controller 1410 causes the write data to be written to the DRAM 160. The read/write controller 1410 then causes the NAND controller 170 to execute a process of writing the write data associated with the write command.

The read/write controller 1410 receives a read command transmitted by the interface controller 130. The read/write controller 1410 causes the NAND controller 170 to execute a process of reading user data associated with the read command. The data read by the NAND controller 170 can be written to the DRAM 160. The read/write controller 1410 can then cause the read data written to the DRAM 160 to be transmitted from the serial interface 120 to the host device 200.

The read/write controller 1410 converts a logical address designated by the read command into a physical address in the NAND memory 110. Also, the read/write controller 1410 performs address conversion by referring to an address conversion table.

FIG. 5 is a diagram illustrating an example of an address conversion table of the first embodiment. The address conversion table has table data indicating a relationship between a logical address and a physical address. The logical address is information for specifying a logical block and a logical page to which the data can be written. The physical address indicates a storage position of data written to the NAND memory 110. In the address conversion table, for example, a logical block address (LBA), a storage position (a physical block address (PBA) or a physical address) on the NAND memory 110 in which data is stored, and a data presence/absence flag indicating whether data has been written within the physical block are associated with each other. The PBA may be represented by a block ID and a page ID, but is not limited thereto.

The block manager 1420 causes read, write, and erase operations to be performed on the NAND memory 110 independently of the write command and the read command. Thereby, the block manager 1420 executes a management process for managing a condition of the NAND memory 110. The management process includes a process of forming a free block, refresh, garbage collection, wear leveling, control of a gear ratio, and slot ring, but is not limited thereto.

The block manager 1420 may include a free block manager (FBM) 1421, a refresh block manager (RBM) 1422, a garbage collection manager (GCM) 1423, and a wear leveling manager (WRM) 1424, but is not limited thereto.

The free block manager 1421 performs a process of securing a predetermined number of physical blocks among physical blocks of the NAND memory 110 as free blocks. Physical blocks of the NAND memory 110 can be roughly classified according to their states as active blocks and free blocks. An active block is a physical block in which valid data is presently stored. A free block is a block in which no valid data is presently stored. After a free block is erased, data can be written thereon. The valid data is data associated with a logical address.

The refresh block manager 1422 determines whether a physical block is required to be refreshed based on a state of error occurrence for each physical block. The refresh block manager 1422 reads valid data from the physical block required to be refreshed and then writes the just read valid data to another physical block.

The garbage collection manager 1423 selects a physical block storing valid data rate from among active blocks based on a ratio of valid data to data in the physical block. The garbage collection manager 1423 reads data written to the selected physical block to then write the just read data to a free block. Thereafter, the garbage collection manager 1423 releases the selected physical block.

The wear leveling manager 1424 causes the NAND controller 170 to read and write data so that the number of times of rewriting or the like is uniform among physical blocks. The wear leveling manager 1424 executes as wear leveling, for example, a process of selecting a write destination for user data when a write command is received. Also, the wear leveling manager 1424 may execute a data rearrangement process as wear leveling process regardless of the reception of a write command.

The gear ratio controller 1430 controls a gear ratio. The gear ratio is a ratio between a frequency at which user data is written and read by the read/write controller 1410 and a frequency at which user data is written and read by the block manager 1420. The gear ratio controller 1430 controls the gear ratio to be a predetermined value. The predetermined value related to the gear ratio is determined by setting of a first program to be activated in the memory system 100.

Also, the gear ratio controller 1430 may execute the slot ring. When reading or writing is executed by the read/write controller 1410 or the block manager 1420, the gear ratio controller 1430 may adjust the execution or non-execution of reading or writing in processing units of reading or writing based on conditions of performance, power consumption, or temperature. The gear ratio controller 1430 adjusts the execution or non-execution of reading or writing so that a performance difference between a use start time of the memory system 100 and a time at which a durable period has elapsed is suppressed. Also, the gear ratio controller 1430 may adjust the execution or non-execution of reading or writing so that the memory system 100 operates within designated power consumption parameters. Further, the gear ratio controller 1430 may adjust the execution or non-execution of reading or writing to suppress heat generation so that the memory system 100 operates within a designated temperature condition.

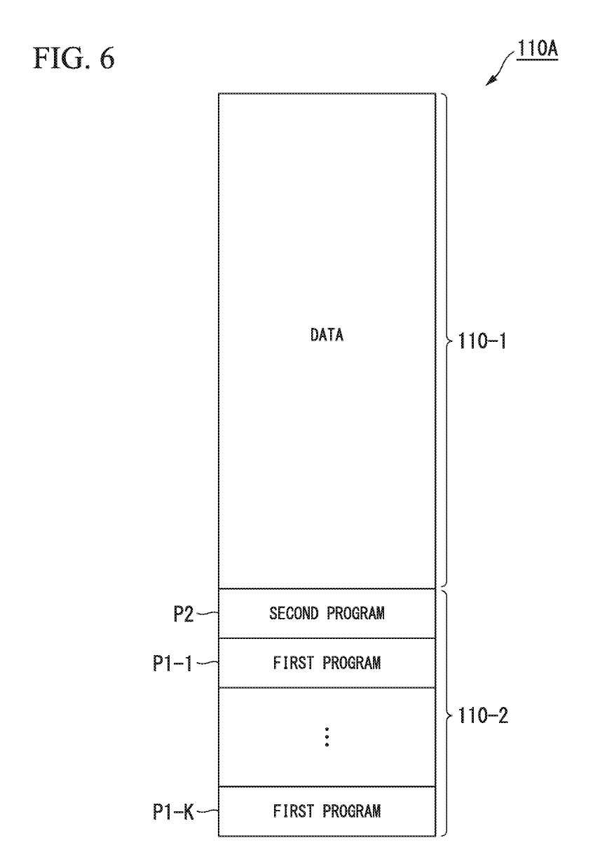

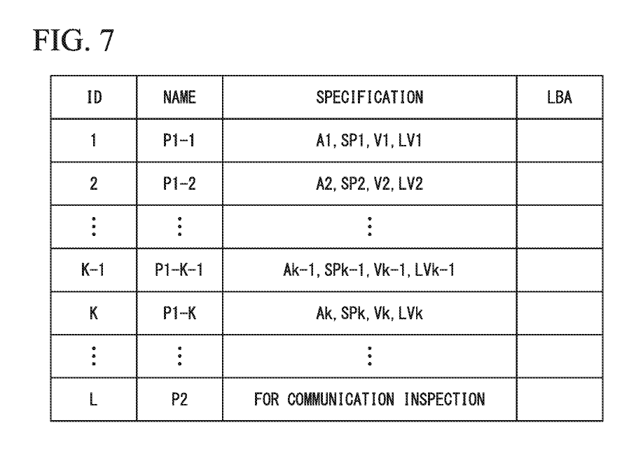

Hereinafter, a plurality of first programs executable in the memory system 100 of the first embodiment will be described. FIG. 6 is a diagram illustrating an example of a region of a NAND memory of the first embodiment. FIG. 7 is a diagram illustrating an example of program information stored in the memory system of the first embodiment.

As illustrated in FIG. 6, a first region 110-1 and a second region 110-2 are included in the storage region 110A in the NAND memory 110. User data as designated by the host device 200 is stored in the first region 110-1. Here, K first programs P1-1 to P1-K and a second program P2 are stored in the second region 110-2. The first programs P1-1 to P1-K may have differences in parameters for a signal transmission process of the serial interface 120. The second program P2 is a program for causing the serial interface 120 to execute a signal transmission process of a command and for selecting one first program P1 from among the plurality of first programs P1 based on a result of the signal transmission process.

Program information illustrated in FIG. 7 is stored in the NAND memory 110. The program information includes information about the plurality of first programs P1-1 to P1-K and information about the second program P2.

As illustrated in FIG. 7, for example, an ID, a name, a specification of parameters, and a logical address (LBA) are associated with each first program P1. The ID is information such as a number for identifying the particular first program P1. The name is a name attached to each first program P1 and is, for example, a character string that may be recognized by a user of the host device 200 or a vendor of the memory system 100. The specification includes a parameter or parameters for setting a signal transmission process of the serial interface 120 for each first program P1. The parameters include signal amplitude A and signal processing scheme SP. Also, the specification may include a read/write speed V [b/s]. Furthermore, the specification may include a level of read/write performance for the memory system 100 and level information LV indicating a level of reliability for the memory system 100. The level information LV may include both or either of the level of the read/write performance and the level of reliability. Also, the level information LV may indicate the level of the read/write performance or the level of the reliability with a step-by-step (incrementing) numerical value or symbol. Further, the level information LV may be information indicating processing content such as a frequency at which a management process is executed.

Also, the logical address is associated with the first program P1, but is not limited thereto. The logical address may be associated with information for reading the first program P1 from the NAND memory 110. The information for reading the first program P1 from the NAND memory 110 may include a physical address in addition to the logical address.

Further, the second program P2 is also associated with an ID, a name, a specification, and a logical address.

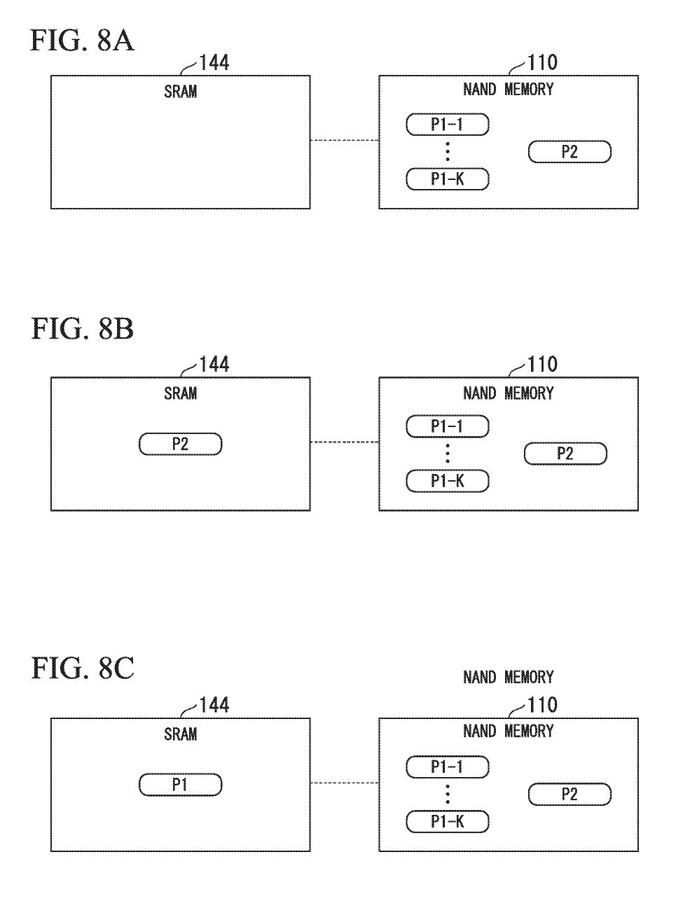

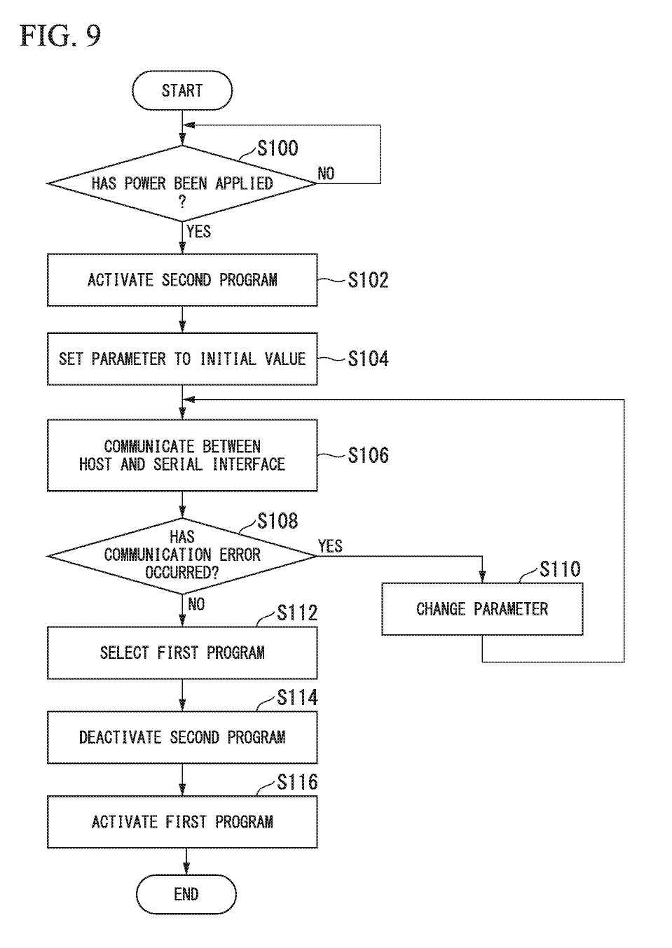

Hereinafter, a process of selecting one from the plurality of first programs P1 stored in the second region 110-2 based on a result of performing communication with the host device 200 using the serial interface 120 and then activating the selected first program P1 in the memory system 100 of the first embodiment will be described. FIGS. 8A, 8B, and 8C are diagrams illustrating examples of programs stored in the NAND memory and the SRAM in the memory system of the first embodiment. FIG. 9 is a flowchart illustrating an example of a flow of a process of activating the first program in the memory system of the first embodiment.

As illustrated in FIG. 8A, if no power is applied to the memory system 100, the plurality of first programs P1-1 to P1-K and the second program P2 are stored in the NAND memory 110 and no program is stored in the SRAM 144. When the memory system 100 is activated (power is applied) (S100), the main controller 140 first activates the second program P2 (S102). At this time, the main controller 140 acquires a logical address corresponding to the second program P2 by referring to program information. Next, the main controller 140 acquires a physical address corresponding to the acquired logical address by referring to the address conversion table. Next, the main controller 140 outputs a read request designating the acquired physical address to the NAND controller 170. As illustrated in FIG. 8B, the main controller 140 writes the second program P2, as read by the NAND controller 170, to the SRAM 144.

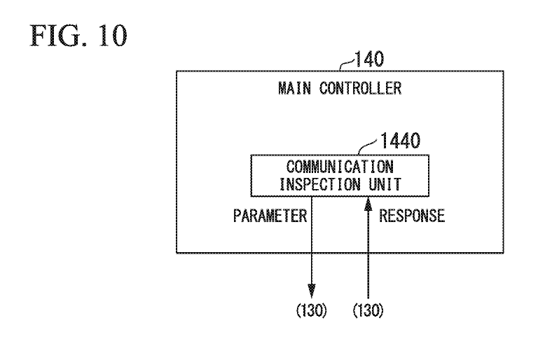

FIG. 10 is a block diagram illustrating an example of the main controller when a second program is activated in the first embodiment. The main controller 140 includes a communication inspection unit 1440. The communication inspection unit 1440 is implemented by the CPU 142 executing the second program P2.

Next, the communication inspection unit 1440 sets a parameter to an initial value (S104). At this time, the main controller 140 outputs the initial value of the parameter to the interface controller 130.

Next, the communication inspection unit 1440 performs communication between the host device 200 and the serial interface 120 (including a signal transmission process) (S106). At this time, the interface controller 130 causes the signal processing unit 124 to modulate a command or data according to the amplitude serving as the initial value and a signal processing scheme and causes the modulated signal to be transmitted from the serial interface 120 to the host device 200.

Next, the communication inspection unit 1440 determines whether a communication error has occurred (S108). At this time, if a response indicating that a signal cannot be decoded by the host device 200 has been received from the interface controller 130, the communication inspection unit 1440 determines that the communication error has occurred. Also, if there is no response even when a predetermined time has elapsed after the transmission of the command from the serial interface 120 to the host device 200, the communication inspection unit 1440 may determine that a communication error has occurred. Further, the communication inspection unit 1440 may determine that a communication error has occurred if the signal transmitted by the host device 200 cannot be decoded.

The communication inspection unit 1440 may determine that a communication error has occurred if a plurality of communication errors has occurred in addition to determining that a communication error has occurred due to one communication error. If the serial interface 120 is based on SATA, the communication inspection unit 1440 counts a value of an event counter in a physical layer (PhyEventCounter) up. If the serial interface 120 is based on PCIe, the communication inspection unit 1440 checks occurrence count-up of a PCIe error. If a value corresponding to the number of occurrences of a communication error has exceeded some threshold value, the communication inspection unit 1440 may determine that a communication error has occurred.

If it is determined that the communication error has occurred, the communication inspection unit 1440 changes a parameter (S110). Next, the communication inspection unit 1440 executes processes of S106 and S108 again after outputting the changed parameter to the interface controller 130. Thereby, the communication inspection unit 1440 eventually retrieves a parameter for which no communication error has occurred based on a result of the signal transmission process.

Once the signal transmission process has been completed without communication error, the communication inspection unit 1440 selects the first program P1 (S112). At this time, the communication inspection unit 1440 selects one first program P1 from the plurality of first programs P1 based on the retrieved parameter associated with successful (non-erroneous) communication. The communication inspection unit 1440 may select, for example, the first program P1 having a parameter closest to the retrieved parameter, but is not limited thereto.

Next, the main controller 140 deactivates the second program P2 (S114). Next, the main controller 140 activates the first program P1 (S116). At this time, the main controller 140 acquires a logical address corresponding to the selected first program P1 with reference to program information. Next, the main controller 140 acquires a physical address corresponding to the acquired logical address with reference to an address conversion table. Next, the main controller 140 outputs a read request designating the acquired physical address to the NAND controller 170. As illustrated in FIG. 8C, the main controller 140 writes the first program P1 read by the NAND controller 170 to the SRAM 144. Subsequently, the main controller 140 implements the read/write controller 1410, the block manager 1420, and the gear ratio controller 1430, as illustrated in FIG. 4.

The main controller 140 acquires the logical address corresponding to the first program P1, reads the first program P1 stored in the NAND memory 110 based on the physical address corresponding to the acquired logical address, and writes the read first program P1 to the SRAM 114.

Also, the main controller 140 may set the retrieved parameter as a parameter of the selected first program P1. At this time, the main controller 140 writes the retrieved parameter to a register of the CPU 142 in place of the parameter set in the first program read from the NAND memory 110.

Also, the communication inspection unit 1440 may determine whether there is compatibility in S108. At this time, the communication inspection unit 1440 may determine that there is no compatibility if communication with the host device 200 is disabled due to the occurrence of a communication error and the memory system 100 cannot recognize the host device 200. Also, the communication inspection unit 1440 may determine that there is no compatibility if there is a difference between an operation when no communication error has occurred and an operation when a communication error has occurred. For example, read/write performance when the communication error has occurred is lower than read/write performance when no communication error has occurred. The communication inspection unit 1440 can move the process to S112 if it is determined that there is compatibility. The communication inspection unit 1440 would move the process to S110 if it is determined that there is no compatibility.

As described above, according to the memory system 100 of the first embodiment, it is possible to select one first program P1 from the plurality of first programs P1-1 to P1-K stored in the second region 110-2 based on performing communication with the host device 200 by the serial interface 120 and then activate the selected first program P1. Thereby, according to the memory system 100 of the first embodiment, it is possible to select a first program P1 having good compatibility with respect to the host device 200 from among the plurality of first programs P1-1 to P1-K. As a result, according to the memory system 100 of the first embodiment, it is possible to automatically select a first program having good compatibility with the host device 200 and improve convenience.

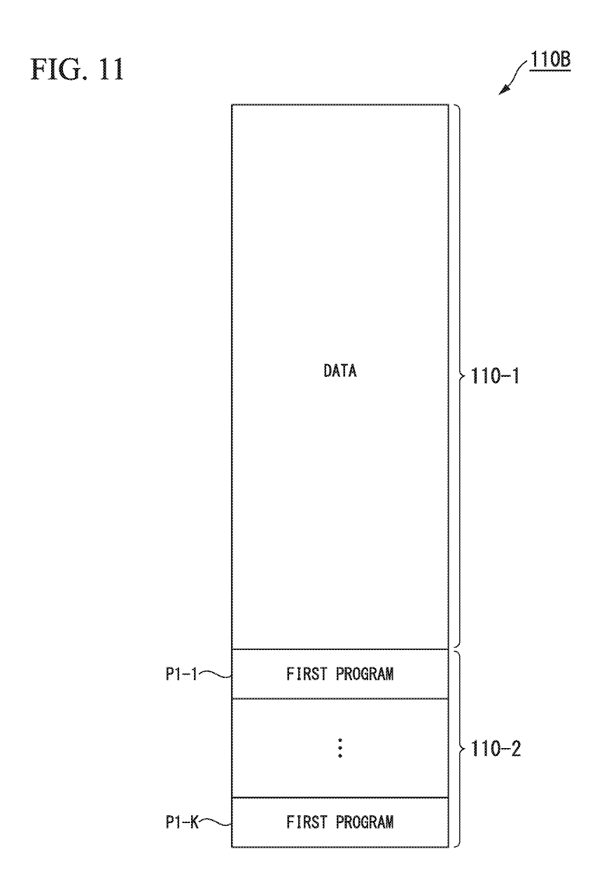

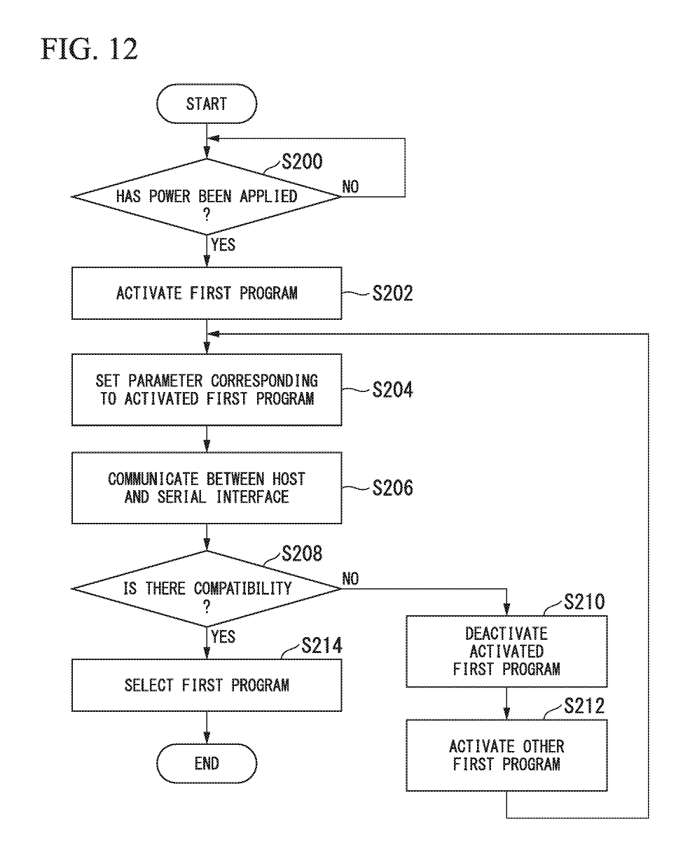

Hereinafter, a second embodiment will be described. Difference(s) from the above-described first embodiment will be mainly described for the second embodiment and a description of common aspects will be omitted. The memory system 100 of the second embodiment causes the plurality of first programs P1-1 to P1-K to be stored in the storage region 110B of the NAND memory 110 without causing or having the second program P2 to be stored therein. FIG. 11 is a diagram illustrating another example of a storage region of the NAND memory of the second embodiment. FIG. 12 is a flowchart illustrating an example of a flow of another process of activating the first program in the memory system of the second embodiment.

First, when power is applied (S200), the main controller 140 activates any first program P1 from among the plurality of first programs P1-1 to P1-K (S202). Next, the main controller 140 sets parameters corresponding to the activated first program P1 (S204). At this time, the main controller 140 acquires parameters by reference to program information for the activated first program P1 and outputs the acquired parameter to the interface controller 130.

Next, the main controller 140 causes communication between the host device 200 and the serial interface 120 (including a signal transmission process) to be performed (S206). At this time, the interface controller 130 causes the signal processing unit 124 to modulate a command or data according to amplitude and the signal processing scheme included in the set parameter and causes a modulated signal to be transmitted from the connector 122 to the host device 200.

Next, the main controller 140 determines whether there is compatibility (S208). If it is determined that there is compatibility, the main controller 140 selects the activated first program P1 from among the plurality of first programs P1-1 to P1-K (S214).

If there is no compatibility, the main controller 140 deactivates the activated first program P1 (S210). Next, the main controller 140 activates another first program P1 different from the just ended first program P1 (S212) and repeats the process subsequent to S204.

According to the memory system 100 of the second embodiment, the activated first program P1 becomes the selected first program P1 from among the plurality of first programs P1-1 to P1-K if there is compatibility between the memory system 100 and the host device 200. As a result, according to the memory system 100 of the second embodiment, it is possible to automatically select a first program P1 from among a plurality of first programs P1-1 P1-K having compatibility with the host device 200 and improve convenience.

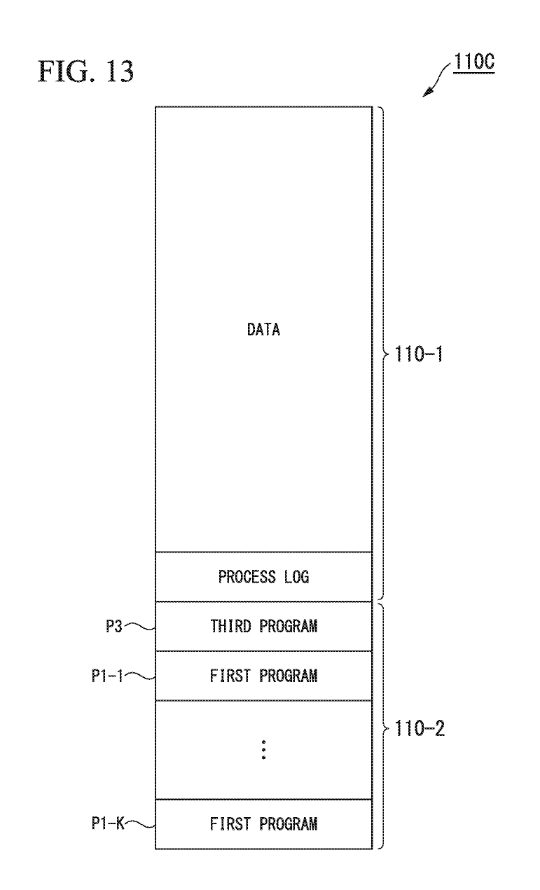

Hereinafter, a third embodiment will be described. Differences from the above-described first embodiment will be mainly described for the third embodiment and a description of common aspects will be omitted. The memory system 100 of the third embodiment stores a third program in the NAND memory 110. FIG. 13 is a diagram illustrating an example of a storage region of the NAND memory in the third embodiment. The third program P3 is stored in the second storage region 110-2 of the storage region 110C. Here, the third program P3 is a program for analyzing the memory system 100 to be run in the main controller 140. In the third program P3, as for the first programs P1, has an ID, a name, and a logical address associated therewith.

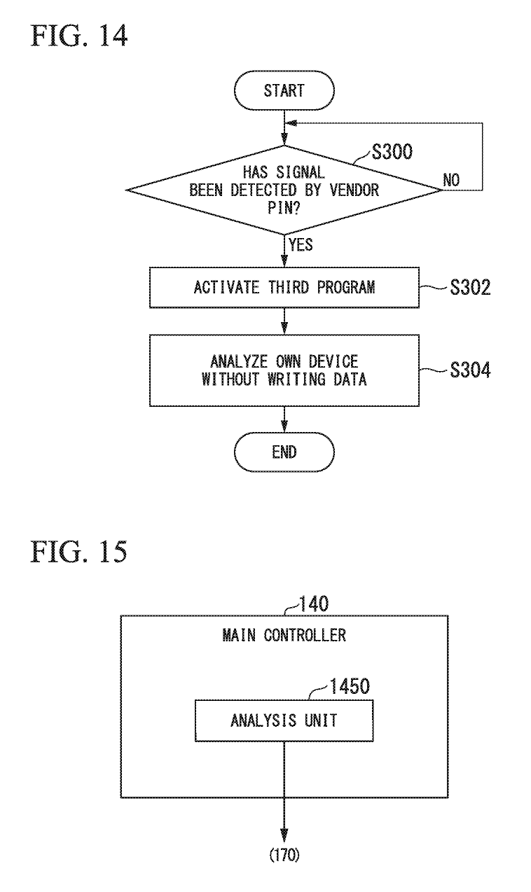

FIG. 14 is a flowchart illustrating an example of a flow of a process in the third embodiment. First, the main controller 140 determines whether a signal has been detected by a vendor PIN (S300). As illustrated in FIG. 3, the vendor PIN is a signal terminal 122a among the plurality of signal terminals 122a and is a signal terminal 122a having an ID of “C.” When a signal is supplied to the signal terminal 122a having the ID of “C,” for example, short-circuiting the vendor PIN with another signal terminal 122a by an operator of the vendor is included. When a signal is supplied to the signal terminal 122a having the ID of “C,” this can be considered to include the inputting of a command indicating an instruction for activating the third program P3. The command indicating the instruction for activating the third program P3 does not overlap a command to be transmitted or received between the host device 200 and the memory system 100 and may be a vendor-specific command.

The main controller 140 does not proceed to the process of S302 if it is determined that no signal has been detected by the vendor PIN. The main controller 140 activates the third program P3 if it is determined that a signal has been detected by the vendor PIN (S302). At this time, the main controller 140 acquires a logical address corresponding to the third program P3 by reference to the program information. Next, the main controller 140 acquires a physical address corresponding to the acquired logical address with respect to an address conversion table. Next, the main controller 140 outputs a read request designating the acquired physical address to the NAND controller 170. The main controller 140 then writes the third program P3, as read by the NAND controller 170, to the SRAM 144. At this time, the main controller 140 reads the third program P3 stored in the NAND memory 110 and activates the third program P3 according to the read data without re-writing the read third program P3 to the NAND memory 110.

FIG. 15 is a block diagram illustrating an example of a main controller when a third program is activated in the third embodiment. The main controller 140 includes an analysis unit 1450. The analysis unit 1450 is implemented by the CPU 142 executing the third program P3.

Next, the analysis unit 1450 analyzes the memory system 100 without writing any data to the NAND memory 110 (S304). The analysis unit 1450 causes the NAND controller 170 to read a process log (see FIG. 13) stored in the NAND memory 110. The analysis unit 1450 specifies a process log corresponding to a cause of a malfunction occurring in the memory system 100, but is not limited thereto. The analysis unit 1450 may specify the cause of the malfunction of the memory system 100 according to another analysis method. At this time, the analysis unit 1450 analyzes the memory system 100 without writing to the NAND memory 110. That is, the analysis unit 1450 executes the third program P3 without otherwise changing a state related to the analyzed memory system 100.

The process log may record predetermined information in time series in a fixed format and is an example of data accumulated in the NAND memory 110. The memory system 100 may store information such as a thread log or an event log in the NAND memory 110 in addition to (or in place of) the process log. In this case, the analysis unit 1450 analyzes the memory system 100 based on the information such as the thread log or the event log in addition to (or in place of) the process log.

A result associated with the analyzing of the memory system 100 by the analysis unit 1450 is written to a region separate from a region to which information indicating a state of the memory system 100 is written among regions of the NAND memory 110 after the analysis of the memory system 100 has ended. The result of analyzing the memory system 100 can be read by an external device connected to the memory system 100. Thereby, the operator of the vendor can check the state of the memory system 100 based on a result of reading to the external device.

In the third embodiment, the plurality of first programs P1-1 to P1-K are stored in the NAND memory 110 in the second region 110-2, as illustrated in FIG. 13, but storage is not limited thereto. One first program P1 may be stored. Also, the second program P2 may be stored in the second region 110-2. If the second program P2 is stored, the main controller 140 performs a process similar to that of the first embodiment. If the second program P2 is not stored, the main controller 140 performs a process similar to that of the second embodiment.

As described above, according to the memory system 100 of the third embodiment, the first program P1 and the third program P3 are both stored in the NAND memory 110. If it is detected that the third program P3 is activated, the memory system 100 of the third embodiment can execute the analysis of the memory system 100 by activating the third program P3. As a result, according to the memory system 100 of the third embodiment, it is possible to execute the analysis of the memory system 100 without loading an analysis program to the memory system 100 by connecting an external device in which the analysis program is saved to the memory system 100.

Also, according to the memory system 100 of the third embodiment, it is possible to analyze a malfunction or the like of the memory system 100 without changing the state of the memory system 100 because the memory system 100 is analyzed without writing data to the NAND memory 110.

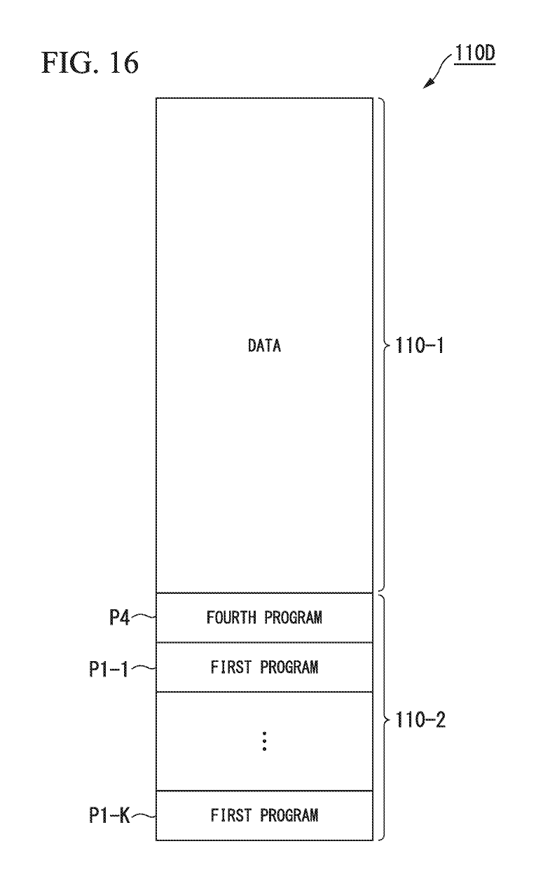

Hereinafter, a fourth embodiment will be described. Differences of the fourth embodiment from the above-described first embodiment will be mainly described and a description of common aspects will be omitted. The memory system 100 of the fourth embodiment stores a fourth program in the NAND memory 110. FIG. 16 is a diagram illustrating an example of a storage region of a NAND memory in the fourth embodiment. The fourth program P4 is stored in the second storage region 110-2 of the storage region 110D. The fourth program P4 is activated if the memory system 100 has malfunctioned and is a program for externally transmitting (exporting) user data stored in the NAND memory 110. Similar to the first program P1, the fourth program P4 is associated with an ID, a name, a specification, and a logical address.

Here, the malfunction of the memory system 100 is the case in which a process completion time of a process executed by the first program P1 is greater than some upper limit value, but malfunctions are not limited thereto. The malfunction of the memory system 100 may also include the case in which a process executed by the first program P1 is deactivated (stopped) due to an error, and the like. Also, the malfunction of the memory system 100 may also include the case in which the main controller 140 determines that the expected lifetime of the memory system 100 has expired or the case in which the main controller 140 determines that the memory system 100 is close to lifetime expiration. The lifetime of the memory system 100 may be measured as a total number of times of writing to physical blocks of the NAND memory 110 reaching an upper limit value, but is not limited thereto.

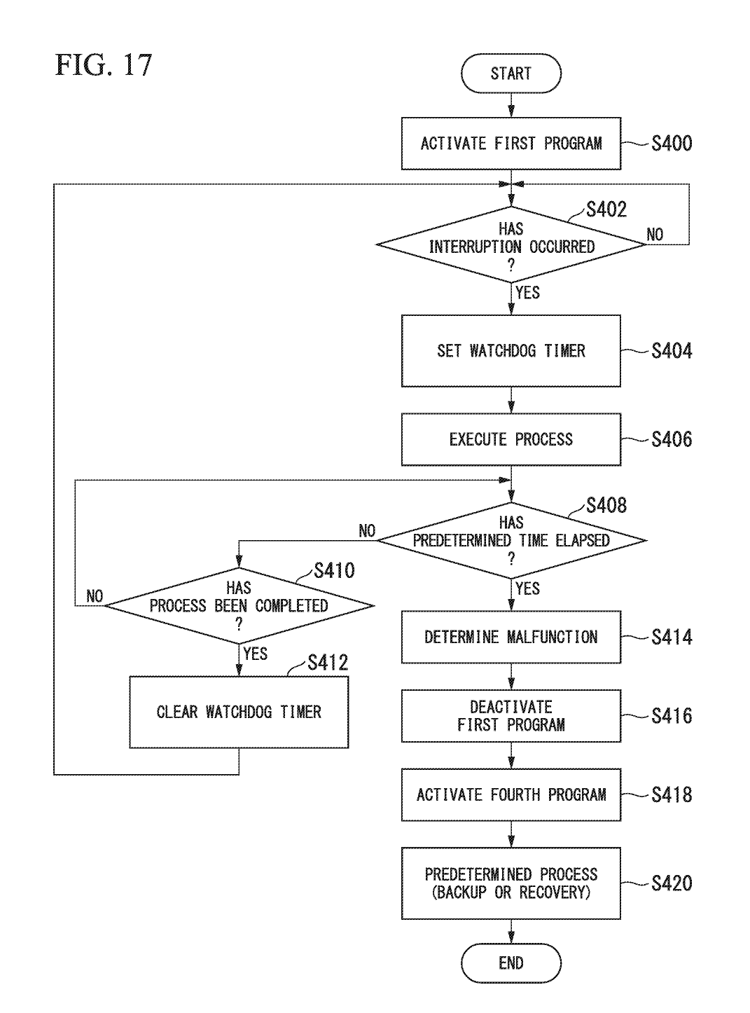

FIG. 17 is a flowchart illustrating an example of a flow of a process in the fourth embodiment. First, the main controller 140 activates the first program P1 (S400). Next, the main controller 140 determines whether interruption has occurred while the first program P1 was being executed (S402). The main controller 140 determines that the interruption has occurred, for example, if the serial interface 120 has received a command transmitted from the host device 200. Also, the main controller 140 can determine that the interruption has occurred if a process for forming a free block by the block manager 1420, a refresh start process, a garbage collection start process, or a wear leveling start process has occurred. The main controller 140 otherwise waits if no interruption has occurred.

When an interruption has occurred, the main controller 140 sets a watchdog timer (S404). At this time, the main controller 140 sets a value corresponding to a time greater than an upper limit value of the processing time when the memory system 100 has not malfunctioned. Next, the main controller 140 executes a process related to the interruption that has occurred (S406). Next, the main controller 140 determines whether a predetermined time has elapsed from the setting of the watchdog timer (S408).

If the predetermined time has not elapsed, the main controller 140 determines whether a process associated with the interruption has been completed (S410). If the process has not been completed, the main controller 140 returns to S408. The main controller 140 clears the watchdog timer if the process associated with the interruption has been completed (S412) and returns to S402.

The main controller 140 determines that there has been a malfunction of the memory system 100 when it is determined that the predetermined time of the watchdog timer has elapsed (S414). Next, the main controller 140 deactivates the first program P1 (S416). Next, the main controller 140 activates the fourth program P4 (S418).

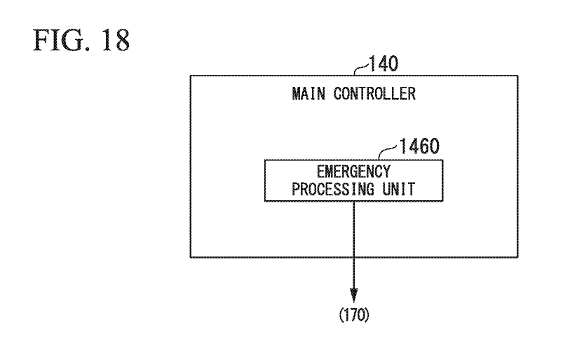

FIG. 18 is a block diagram illustrating an example of a main controller when a fourth program is activated in the fourth embodiment. The main controller 140 includes an emergency processing unit 1460. The emergency processing unit 1460 is implemented by the CPU 142 executing the fourth program P4.

Next, the emergency processing unit 1460 executes a predetermined process as an emergency process with respect to the malfunction (S420). At this time, the emergency processing unit 1460 externally transmits data stored in the NAND memory 110 as a predetermined process. Thereby, the emergency processing unit 1460 executes a backup process in which the transmitted data from the NAND memory 110 is stored in an external storage device. The external storage device may be the host device 200, but is not limited thereto. The external storage device may be a storage device other than the memory system 100 to which the host device 200 saves backup data. In this case, the host device 200 stores the received backup data in another storage device (other than memory system 100) if the backup data has been received from the memory system 100. Also, the process for reading the data to be transmitted from the memory system 100 as executed by the emergency processing unit 1460 may have lower read performance than a read process to be executed by the read/write controller 1410.

The emergency processing unit 1460 may change a set parameter value of the first program P1 as a predetermined process in place of (or in addition to) the backup process. The set parameter value of the first program P1 is data necessary to perform the process of the first program P1. The set parameter value of the first program P1 may be a calculation result of the first program P1, data for use in the calculation of the first program P1, and an address of the data, but is not limited thereto. At this time, the emergency processing unit 1460 rewrites the set parameter value of the first program P1 stored in the register to an initial value. Thereby, the main controller 140 recovers the memory system 100 by continuing the process of the first program P1.

Also, a malfunction is determined based on the processes of 5404 to 5412 in the fourth embodiment, but is not limited thereto. It is only necessary for the main controller 140 to determine that the memory system 100 has malfunctioned when a state in which the memory system 100 cannot be operated normally has been detected.

In the fourth embodiment, the plurality of first programs P1-1 to P1-K are stored in the NAND memory 110 in the second region 110-2 as illustrated in FIG. 16, but is not limited thereto. One first program P1 may be stored. Also, the second program P2 may be stored in the second region 110-2. If the second program P2 is stored, the main controller 140 performs a process similar to that of the first embodiment. If the second program P2 is not stored, the main controller 140 performs a process similar to that of the second embodiment. Further, the third program P3 may be stored in the second region 110-2. If the third program P3 is stored, the main controller 140 performs a process similar to that of the third embodiment.

As described above, the memory system 100 of the fourth embodiment stores the fourth program P4 in the NAND memory 110 in advance and activates the fourth program P4 upon ending the first program P1 if it is determined that a malfunction has occurred. According to the memory system 100 of the fourth embodiment, it is possible to prevent an influence of the malfunction of the first program P1 from being extended by executing a predetermined process by the emergency processing unit 1460 when the malfunction of the first program P1 has occurred.

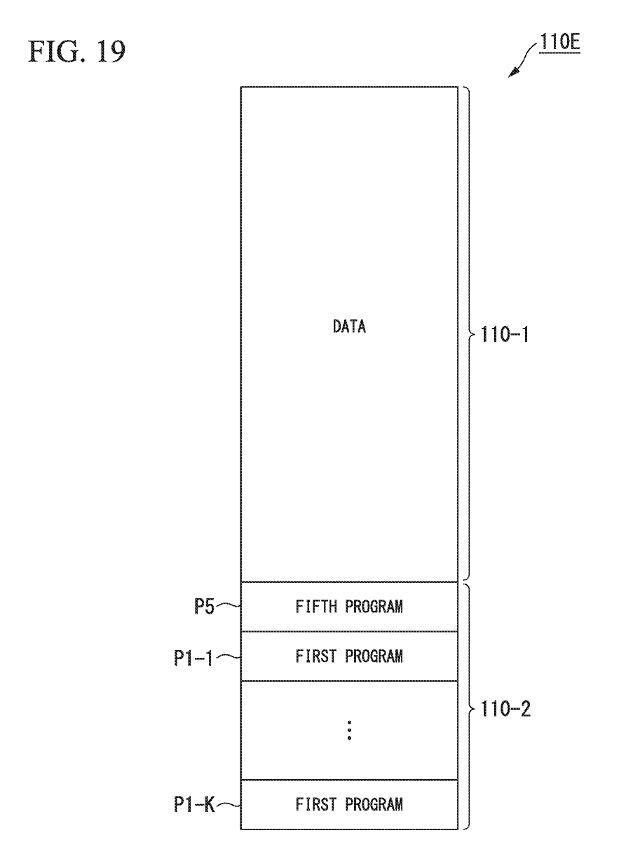

Hereinafter, a fifth embodiment will be described. Differences in the fifth embodiment from the above-described first embodiment will be mainly described and a description of common aspects will be omitted. The memory system 100 of the fifth embodiment stores a fifth program in the NAND memory 110. FIG. 19 is a diagram illustrating an example of a storage region of a NAND memory in the fifth embodiment. The fifth program P5 is stored in the second storage region 110-2 of the storage region 110D. The fifth program P5 causes the main controller 140 to test the memory system 100. Similar to the first program P1, the fifth program P5 is associated with an ID, a name, a specification, and a logical address.

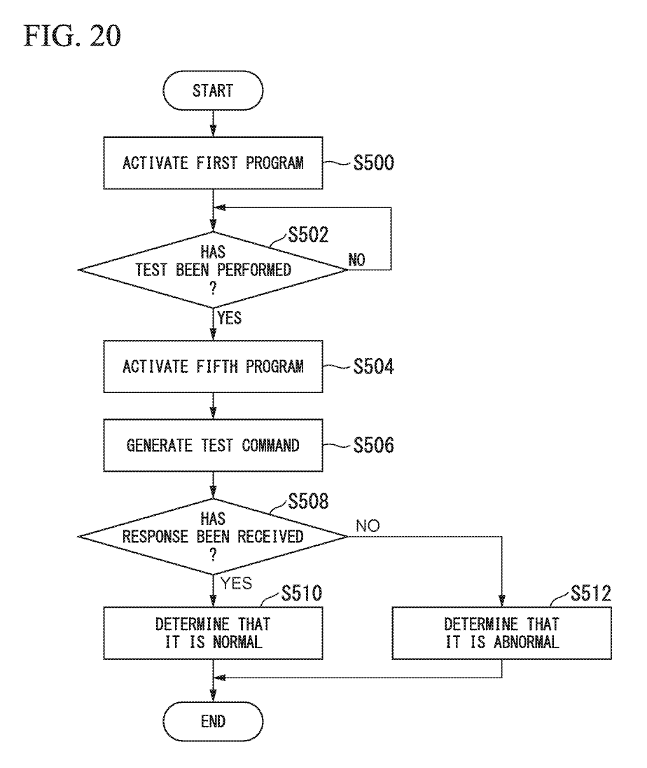

FIG. 20 is a flowchart illustrating an example of a flow of a process in the fifth embodiment. First, the main controller 140 activates the first program P1 (S500). Next, the main controller 140 determines whether a test is to be performed while the first program P1 is being executed (S502). At this time, the main controller 140 determines, for example, whether a signal has been detected by a vendor PIN. As illustrated in FIG. 3, the vendor PIN is a signal terminal 122a having the ID of “C” among a plurality of signal terminals 122a. When a signal is supplied to the signal terminal 122a having the ID of “C,” for example, short-circuiting the vendor PIN with another signal terminal 122a by the operator of the vendor is included. When a signal is supplied to the signal terminal 122a having the ID of “C,” inputting a command providing an instruction for activating the fifth program P5 is included. The command indicating the instruction for activating the fifth program P5 does not overlap a command to be transmitted or received between the host device 200 and the memory system 100 and a command for activating another program and may be a vendor-specific command.

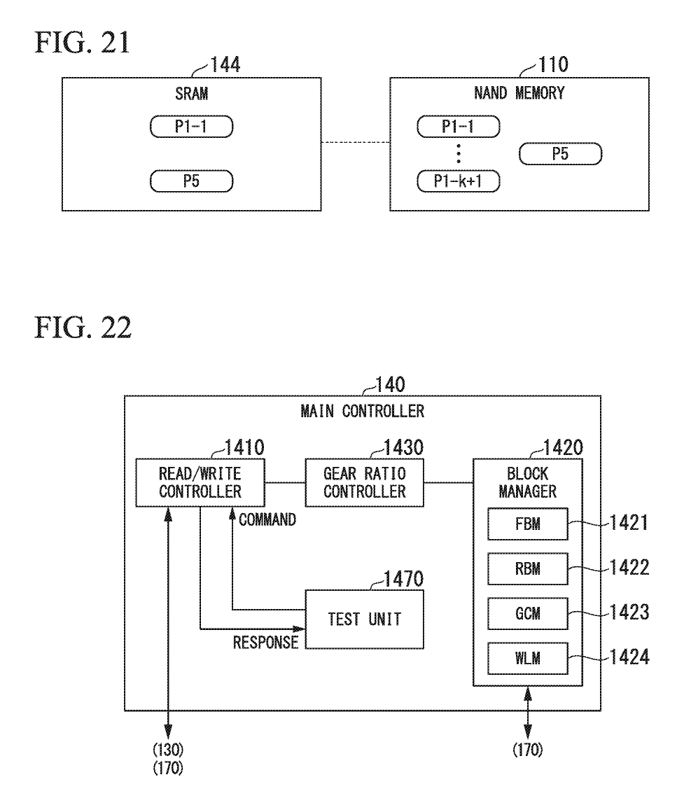

The main controller 140 activates the fifth program P5 if it is determined a test has been instructed to be performed (S504). At this time, the main controller 140 reads the fifth program P5 from the NAND memory 110 with reference to program information. The main controller 140 writes the read fifth program P5 to the SRAM 144. Thereby, the main controller 140 writes the fifth program P5 to the SRAM 144 in addition to the first program P1, which has already been activated, as illustrated in FIG. 21. That is, the main controller 140 simultaneously executes the first program P1 and the fifth program P5. FIG. 21 is a diagram illustrating an example of programs stored in a NAND memory and an SRAM in the memory system of the fifth embodiment.

FIG. 22 is a block diagram illustrating an example of a main controller when a fifth program has been activated in the fifth embodiment. The main controller 140 includes a test unit 1470 in addition to the read/write controller 1410, the block manager 1420, and the gear ratio controller 1430. The test unit 1470 is implemented by the CPU 142 executing the fifth program P5.

Next, the test unit 1470 generates a command obtained by simulating a command that would be transmitted from the host device 200 to the serial interface 120 (S506). Hereinafter, the command obtained by simulating the command that would be transmitted from the host device 200 to the serial interface 120 is referred to as a “test command.” The test unit 1470 determines whether a response has been received with respect to the generated test command (S508). If the response has been received, the test unit 1470 determines that it is normal (S510). If no response has been received, the test unit 1470 determines that it is abnormal (S512).

In 5506, the test unit 1470 generates the test command. This test command can be a write command, a read command, or an erase command. The test command is transferred from the test unit 1470 to the read/write controller 1410. At this time, the test unit 1470 generates a test write command designating a logical address.

The read/write controller 1410 acquires a test write command generated by the test unit 1470. The read/write controller 1410 then transmits a write request based on the test write command to the NAND controller 170. Thereby, the read/write controller 1410 receives a response to the write request from the NAND controller 170 when writing has been completed normally. The read/write controller 1410 transmits a response for the host device 200 when the response to the write request has been received.

The test unit 1470 determines that the memory system 100 is operating normally if the response for the host device 200 transmitted by the read/write controller 1410 has been received. On the other hand, if the main controller 140, the NAND controller 170, or the NAND memory 110 is abnormal, then the test unit 1470 cannot receive the response to the write test command. If the response cannot be received, the test unit 1470 determines that the memory system 100 is abnormal.

A plurality of first programs P1-1 to P1-K are stored in the NAND memory 110 in the second region 110-2 in the fifth embodiment as illustrated in FIG. 19, but are not limited thereto. One first program P1 may be stored. Also, the second program P2 may be stored in the second region 110-2. If the second program P2 is stored, the main controller 140 performs a process similar to that of the first embodiment. If the second program P2 is not stored, the main controller 140 performs a process similar to that of the second embodiment. Further, the third program P3 may be stored in the second region 110-2. If the third program P3 is stored, the main controller 140 performs a process similar to that of the third embodiment. Further, the fourth program P4 may be stored in the second region 110-2. If the fourth program P4 is stored, the main controller 140 performs a process similar to that of the fourth embodiment.

As described above, the memory system 100 of the fifth embodiment pre-stores the fifth program P5 in the NAND memory 110 and activates the fifth program P5 in conjunction with the first program P1. According to the memory system 100 of the fifth embodiment, it is possible for the test unit 1470 to perform the test of the memory system 100. As a result, according to the memory system 100 of the fifth embodiment, it is possible to perform the test of the memory system 100 without connecting an external device to test the memory system 100. Thereby, according to the fifth embodiment, for example, it is possible to save space in a manufacturing process and reduce costs.

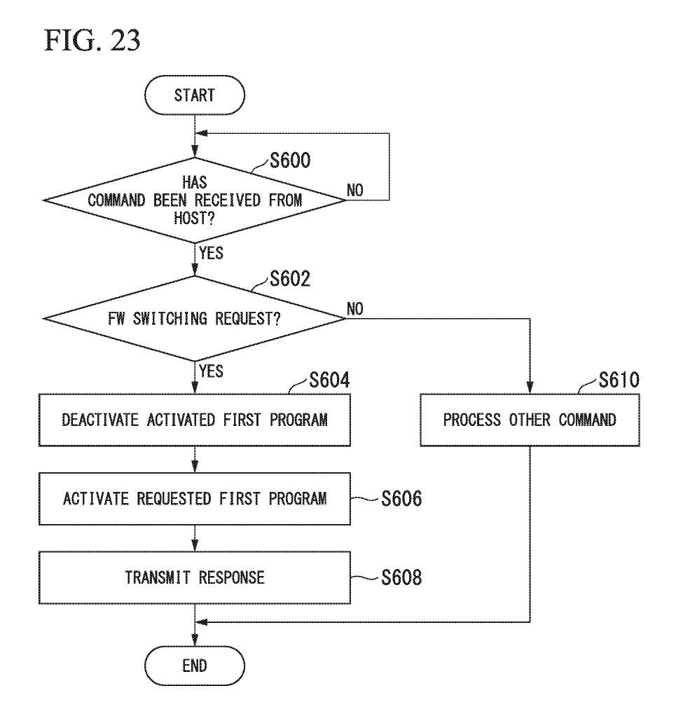

Hereinafter, a modified example of the above-described embodiments will be described. FIG. 23 is a flowchart illustrating the modified example. Here, the main controller 140 determines whether a command has been received from the host device 200 (S600). If the command received from the host device 200 has been received, the main controller 140 determines whether it is or includes a firmware (FW) switching request (S602). If the interface standard on which the serial interface 120 is based is NVMe, the main controller 140 may determine whether the request is a request defined in NVMe.

If the interface standard on which the serial interface 120 is based is SATA, it can be determined whether there has been a firmware (FW) switching request by analyzing a vendor-specific command other than the SATA standard. An unused command code among command codes of SATA can be allocated as a command corresponding to the firmware switching request for the vendor-specific command.

The main controller 140 performs a process corresponding to another command if the request included in the command is not a firmware switching request (S610).

The main controller 140 deactivates the currently activated first program P1 if the request included in the command is the firmware switching request (S604). Next, the main controller 140 activates the requested first program P1 (S606). Next, the main controller 140 transmits a response according to the switching request to the host device 200 (S608).

In the modified example, the memory system 100 may transmit program information to the host device 200 with respect to a program information transmission request received from the host device 200. Thereby, the memory system 100 can present the name, the specification, and the like of the first program P1 to the user.

According to the modified example, it is possible to switch firmware based on a request received from the host device 200. The memory system 100 can enable the user to select a user-desired first program P1, for example, among the plurality of first programs P1-1 to P1-K. Thereby, according to the modified example, the user is allowed to determine which of read/write performance and reliability is prioritized and it is possible to improve convenience of the memory system 100.

In the modified example, the memory system 100 may add or erase firmware based on a request received from the host device 200 in addition to switching firmware based on a request received from the host device 200. Further, the memory system 100 may erase already stored firmware and add new firmware if a capacity of the second storage region 110-2 is at an upper limit value when a request for adding firmware is received.

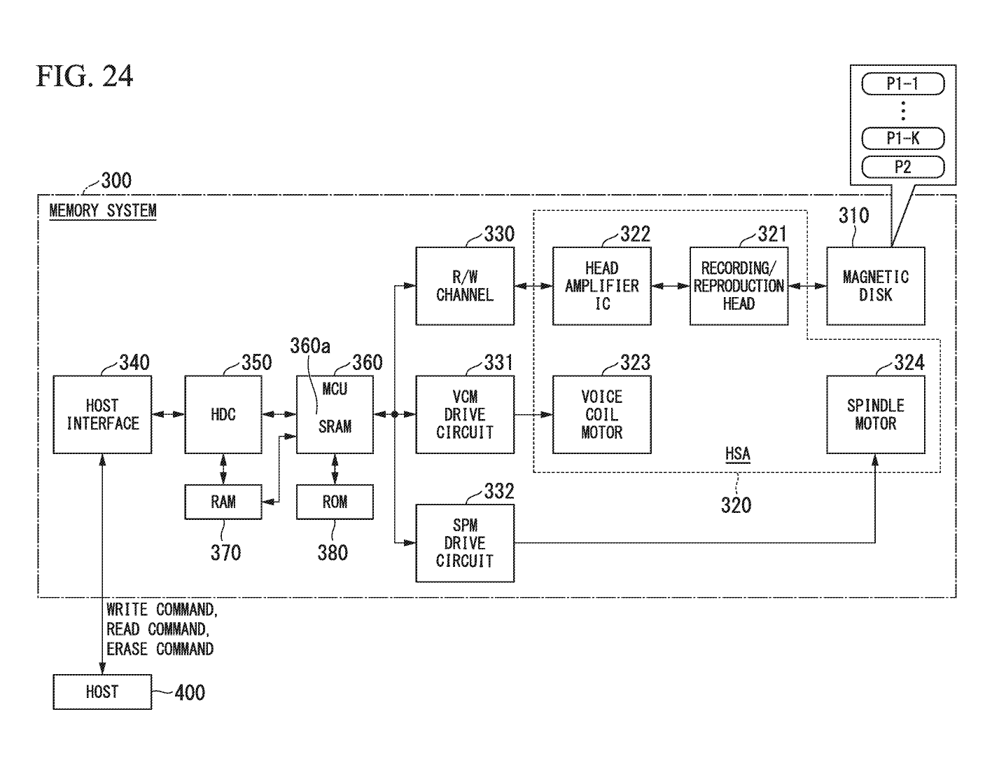

Hereinafter, a sixth embodiment will be described. Differences in the sixth embodiment from the above-described first embodiment will be mainly described and a description of common aspects will be omitted. FIG. 24 is a diagram illustrating an example of a memory system of the sixth embodiment. The memory system 300 of the sixth embodiment includes a magnetic disk 310, a head stack assembly (HSA) 320, a read/write channel (R/W channel in FIG. 24) 330, a voice coil motor (VCM) drive circuit 331, a spindle motor (SPM) drive circuit 332, a host interface 340, a hard disk controller (HDC) 350, a microcontroller unit (MCU) 360, a DRAM 370, and a read only memory (ROM) 380, but is not limited thereto.

The HDC 350 and the MCU 360 are examples of “controllers.” The memory system 300 communicates with a host device 400. The host device 400 transmits a read command for instructing the memory system 300 to read data, a write command for instructing the memory system 300 to write data, an erase command for instructing the memory system 300 to erase data, and the like. In response to the request from the host device 400, the memory system 300 writes information to the magnetic disk 310 and reads information written to the magnetic disk 310.

The magnetic disk 310 is an example of a storage medium. The magnetic disk 10 is a disk (a platter) in which a magnetic recording layer is formed on a front/rear surface of a substrate such as aluminum or glass. The magnetic disk 10 may be constituted of a single disk or may be configured by stacking a plurality of disks in a thickness direction of the disks.

The HSA 320 includes a recording/reproduction head 321, a head amplifier IC 322, a voice coil motor 323, and a spindle motor 324.

The recording/reproduction head 321 is mounted on a head arm and moved relative to the magnetic disk 310 while floating above the magnetic disk 310 according to driving of the voice coil motor 323. The recording/reproduction head 321 may be a thin film head using an electromagnet for both recording and reproduction or may be a combination of a reproduction-only head implemented by an MR head using a semiconductor of giant magneto resistance (GMR), tunnel magneto resistance (TMR), or the like and a recording-only head implemented by a thin film head.

If user data is being written, the recording/reproduction head 321 changes a magnetization direction of the magnetic recording layer of the magnetic disk 10 by generating a magnetic field based on an electrical signal supplied by the head amplifier IC 322. Thereby, the recording/reproduction head 321 writes the user data to the magnetic disk 10.

Also, if user data is being read, the recording/reproduction head 321 generates an electrical signal corresponding to the magnetization direction of the magnetic recording layer of the magnetic disk 310 while moving along the magnetic disk 310. The recording/reproduction head 321 supplies the generated electrical signal to the read/write channel 330 via the head amplifier IC 322.

The head amplifier IC 322 amplifies a signal intensity of the electrical signal supplied by the recording/reproduction head 321. Also, the head amplifier IC 322 converts the user data supplied by the read/write channel 330 into an electrical signal and supplies the electrical signal to the recording/reproduction head 321.

The voice coil motor 323 drives the HSA 320 according to a drive current supplied by the VCM drive circuit 331. Thereby, the voice coil motor 323 is moved to an outside or an inside along a radial direction of the magnetic disk 310 (or in a diagonal direction forming an angle with the radial direction) and is moved between tracks TR. The radial direction is a direction passing through the center of the magnetic disk.

The spindle motor 324 rotates the magnetic disk 310 according to a drive current supplied by the SPM drive circuit 332. For example, the spindle motor 324 is a direct current (DC) brushless motor.

The read/write channel 330 is implemented by, for example, hardware such as LSI, ASIC, or FPGA. The read/write channel 330 encodes user data supplied by the HDC 350 via the MCU 360 into a data string having a predetermined format. The read/write channel 330 supplies the encoded data string to the head amplifier IC 322.

Also, the read/write channel 330 decodes an electrical signal read by the recording/reproduction head 321 and amplified by the head amplifier IC 322 and supplies the decoded electrical signal to the HDC 350 via the MCU 360. Also, if dynamic flying height control (DFH) technology is adopted in the recording/reproduction head 321, the read/write channel 330 may supply a current to a heater for heating the recording/reproduction head 321.

The VCM drive circuit 331 receives a control signal from the MCU 360 and supplies a drive current to the voice coil motor 323. The SPM drive circuit 332 receives a control signal of the MCU 360 and supplies a drive current to the spindle motor 324.

The host interface 340 is an example of a communication interface. The host interface 340 communicates with the host device 400. The host interface 40 receives a write command for requesting writing of user data for the magnetic disk 310, a read command for requesting reading of user data from the magnetic disk 310, or another command from the host device 400.

Also, the host interface 340 transmits user data read in response to the received read command to the host device 400 which is a transmission source of the read command.

Also, the host interface 340 may supply a command on which signal processing is performed to the HDC 350 of a subsequent stage or the like after predetermined signal processing is performed on the command received from the host device 400.

The HDC 350 temporarily stores user data included in the write command received by the host interface 340 in a write buffer (not illustrated) of the DRAM 370. Also, the HDC 350 temporarily stores user data read from the magnetic disk 310 in a read buffer (not illustrated) of the DRAM 370 according to control by the MCU 360.

The MCU 360 writes or reads user data in the order stored in the write buffer stored in the DRAM 370. The MCU 360 is required to await writing or reading of the user data until movement of the recording/reproduction head 321 onto a target track TR is completed. Accordingly, the HDC 350 may switch the storage order of the user data in the write buffer so that a movement time of the recording/reproduction head 321 is minimized, that is, so that a drive amount of the voice coil motor 323 is minimized, to increase a response speed with respect to a command of the host device 400.

The magnetic disk 310 includes a first region and a second region. In the first region, user data designated by the host device 400 is stored. In the second region, K first programs P1-1 to P1-K and the second program P2 are stored. In the second region, the third program P3, the fourth program P4, or the fifth program P5 may be stored in place of the second program P2 in accordance with the above-described embodiments.

The MCU 360 includes an SRAM 360a. It functions as a cache memory of the MCU 360. Programs to be executed by the HDC 350 and the MCU 360 are written to the SRAM 360a. The HDC 350 and the MCU 360 execute a program written to the SRAM 360a. The HDC 350 and the MCU 360 perform a read operation, a write operation, and an erase operation based on the command while executing the first program P1. The HDC 350 and the MCU 360 are made to communicate with the host device 400 through the host interface 340 by execution of the second program P2. The HDC 350 and the MCU 360 select one first program P to be activated from among the plurality of first programs P1-1 to P1-K stored in the magnetic disk 310 based on a communication result.

The MCU 360 may store the first programs P1-1 to P1-K in the magnetic disk 310 without storing the second program P2 in a manner similar to that described in the second embodiment. In this case, the MCU 360 selects the activated first program P1 as one program to be activated among the plurality of first programs P1-1 to P1-K when there is compatibility between the memory system 400 and the host device 400.

As described for the third embodiment, the MCU 360 may store the third program P3 in the magnetic disk 310. In this case, if it is detected that the third program P3 has been activated, the MCU 360 executes the analysis of the memory system 100 according to the third program P3.

The MCU 360 may store the fourth program P4 in the magnetic disk 310 as described in the fourth embodiment. In this case, the MCU 360 activates the fourth program P4 upon ending the first program P1 if it has been determined that a malfunction has occurred. Thereby, it is possible to perform a predetermined process by executing the fourth program P4 when a malfunction of the first program P1 has occurred.

The MCU 360 may store the fifth program P5 in the magnetic disk 310 as described for the fifth embodiment. In this case, the MCU 360 activates the fifth program P5 in addition to the first program P1. Thus, it is possible to test the memory system 300 without making a connection to an external testing device.

According to at least one embodiment described above, it is possible to select a first program having good compatibility with a host device from among a plurality of possible first programs because the storage medium has a first region 110-1 for storing data designated by the host and a second region 110-2 for storing the plurality of first programs having difference in parameters for setting a signal transmission process of a communication interface and a controller which selects and activates the appropriate first program from the plurality of first programs based on performing communication with the host device through a communication interface.

While certain embodiments have been described these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a communication interface for transmitting commands and data to a host and receiving commands and data from the host;
a storage medium having a first region for storing user data and a second region storing a plurality of first programs, each first program for setting parameters of a signal transmission process to be performed using the communication interface, each first program having at least one different parameter from the other first programs in the plurality; and
a controller configured to select and execute a first program from the plurality of first programs according to a result of a first communication attempt between the communication interface and the host.

2. The memory system according to claim 1, wherein
a second program is stored in the second region, the second program for causing the controller to perform the first communication attempt and to select the first program from the plurality of first programs according to the result of the first communication attempt, and
the controller is configured to execute the second program when the controller is first turned on.

3. The memory system according to claim 2, wherein the controller determines a communication parameter based on the result of the first communication attempt and selects the first program from the plurality of first programs based on the communication parameter.

4. The memory system according to claim 3, wherein the communication parameter comprises information indicating signal amplitude and signal processing format of signals that can be successfully transmitted from the communication interface to the host.

5. The memory system according to claim 4, wherein the controller is configured to set a parameter of the first program that is selected from among the plurality of first programs to the communication parameter.

6. The memory system according to claim 1, wherein the controller is configured to:
execute a first first program from among the plurality of first programs when the controller is first turned on,
perform a determination of whether the host is compatible with the signal transmission process performed using the communication interface with parameters of the signal transmission process being set according to the first program, and
deactivate the first program and execute another first program from the plurality of first programs when it has been determined the host is incompatible with the signal transmission process performed with the parameters of the signal transmission process being set according to the first program.

7. The memory system according to claim 1, wherein
a third program is stored in the second region, the third program causing the controller to be configured to read information from a log stored in the storage medium without writing any additional data to the storage medium.

8. The memory system according to claim 1, wherein
the controller is configured to determine whether a malfunction has occurred, deactivate the first program and execute a fourth program stored in the second region of the storage medium, the fourth program causing the controller to be configured to execute a predetermined process of transmitting user data stored in the first region of the storage medium to an external device.

9. The memory system according to claim 1, wherein
the controller is configured to determine whether a malfunction has occurred, deactivate the first program and execute a fourth program stored in the second region of the storage medium, the fourth program causing the controller to be configured to select and execute a different first program from the plurality of first programs.

10. The memory system according to claim 1, wherein
a fifth program is stored in the second region of the storage medium, the fifth program operating along with the first program and causing the controller to generate a test command and determine whether operation is abnormal according to a response to the test command.

11. The memory system according to claim 1, wherein the storage medium is a non-volatile semiconductor memory.

12. The memory system according to claim 1, wherein the storage medium is a magnetic disk.

13. A memory system controlling method, comprising:
selecting a first program from a plurality of first programs based on a first communication attempt between a communication interface and a host, the plurality of first programs being stored in a region of a storage medium, each first program when executed setting parameters of a signal transmission process to be performed using the communication interface; and
executing the selected first program from the plurality of first programs, wherein
each first program has at least one different parameter from the other first programs in the plurality of first programs.

14. The memory system controlling method according to claim 13, comprising:
performing the first communication attempt when the memory system is first turned on.

15. The memory system controlling method according to claim 14, comprising:
determining a communication parameter based on the result of the first communication attempt, wherein
the first program from the plurality of first programs is selected based on the communication parameter.

16. The memory system controlling method according to claim 15, wherein the communication parameter comprises information indicating a signal amplitude and a signal processing format of signals that can be successfully transmitted from the communication interface to the host.

17. The memory system controlling method according to claim 13, further comprising:
executing a first program from the plurality of first programs when the memory system is first turned;
transmitting a signal between the communication interface and the host using parameters of the signal transmission process set according to the first program;
performing a determination of whether the host is compatible with signal transmission process performed using the communication interface with the parameters of the signal transmission process set according to the first program, the determination being based on the result of the transmitting of the signal between the communication interface and the host; and
deactivating the first program and executing another first program from the plurality of first programs when it has been determined the host is incompatible with the signal transmission process performed using the communication interface with the more parameters of the signal transmission process set according to the first program.

18. The memory system controlling method according to claim 13, further comprising:
detecting a signal on a vendor pin in the communication interface; and
executing a program causing a state of the memory system to be analyzed without any additional data being written to the storage medium when the signal on the vendor pin is detected.

19. The memory system controlling method according to claim 13, comprising:
determining whether a malfunction has occurred in the memory system while the selected first program is executing;
deactivating the selected first program if it is determined that the malfunction has occurred in the memory system; and
executing a program causing any user data stored in the storage medium to be exported.

20. The memory system controlling method according to claim 13, comprising:
executing a program while the selected first program is also executing;
generating a test command according to the program, the test command simulating a command being transmitted from the host to the communication interface; and
determining whether the memory system is operating abnormally based on a result produced in response to the test command.
